(19) United States
(12) Patent Application Publication
(10) Pub. No.: US 2005/0200238 A1
(43) Pub. Date: Sep. 15, 2005

(54) Dielectric polymer actuator and inchworm robot using same

(75) Inventors: Choong Nam Park, Suwon (KR); Young Kwan Lee, Seoul (KR); Jae do Nam, Seoul (KR); Hyouk Yeol Choi, Gunpo (KR); Ja Choon Koo, Seoul (KR); Kwang Mok Jung, Anyang (KR)

Correspondence Address: VOLPE AND KOENIG, P.C., UNITED PLAZA, SUITE 1600, 30 SOUTH 17TH STREET, PHILADELPHIA, PA, 19103, US

(73) Assignees: Samsung Electro-Mechanics Co., Ltd., Suwon (KR); Sungkyunkwan University, Seoul (KR)

(21) Appl. No.: 11/076,705

(22) Filed: Mar. 10, 2005

(30) Foreign Application Priority Data
Mar. 10, 2004 (KR) 10-2004-16153
Jun. 15, 2004 (KR) 10-2004-43974

(51) Int. Cl. H01L 41/08

(52) U.S. Cl. 310/328

(57) ABSTRACT

The present invention provides a dielectric polymer actuator and an inchworm robot using the same. The dielectric polymer actuator comprises a laminate-type actuating part and a frame. The laminate-type actuating part is provided with at least one dielectric polymer film which has first and second surfaces positioned opposite to each other and a side interposed between the first and second surfaces and which includes an incompressible dielectric polymer. First and second compliant electrodes are connected to the first and second surfaces. The frame is formed along the side of the dielectric polymer film so that prestrain applied to the dielectric polymer film is about zero. When a voltage is applied through the first and second compliant electrodes to the dielectric polymer film, the laminate-type actuating part is warped in any one direction of first and second surface directions.

### RELATED APPLICATION

The present invention is based on, and claims priority from, Korean Application No. 2004-16153 filed Mar. 10, 2004 and Korean Application No. 2004-43974 filed Jun. 15, 2004, the disclosure of which is incorporated by reference herein in its entirety.

### BACKGROUND OF THE INVENTION

1. Field of the Invention

The present invention relates, in general to a dielectric polymer actuator and, more particularly, to a dielectric polymer actuator, which generates significant displacement without using prestrain causing degradation, and an inchworm robot using the same.

2. Description of the Related Art

Up to date, an actuator, which has most frequently been used in a micro robot, has mostly been based on an electromagnetic mechanism like an electric motor. Many studies of piezoelectric devices, shape memory alloys, or micro robots using electroactive polymers, have recently been conducted.

Particularly, an actuator using an electroactive polymer, which is alternatively called an artificial muscle actuator, is receiving attention as a substitute technology for a conventional technology employing a conventional actuator, such as an electric motor. The electroactive polymer contains various materials, and may be applied to various fields because it is possible to develop various types of actuators according to characteristics and advantages/disadvantages of the materials.

Of the electroactive polymers, an incompressible dielectric polymer, which is alternatively called a dielectric elastomer, is recently being watched with keen interest. Even though the dielectric polymer requires a relatively high voltage power source, it has the advantages of ease of actuation and processing, rapid response, and low price.

The actuation mechanism of the incompressible dielectric polymer is based on thickness reduction of a dielectric polymer film caused by an electric field and/or an area increase of the film due to the thickness reduction. At this stage, the thickness reduction of the dielectric polymer film results from an effective pressure which is applied in a direction of the electric field. The effective pressure (σ_{z}) may be calculated by the following Equation 1.

$${σ}_{z} = - {ɛ}_{o} {ɛ}_{r} {E}^{2} = - {ɛ}_{o} {{ɛ}_{r} ( \frac{V}{t} )}^{2} \qquad Equation 1$$

In Equation 1, E is the electric field, t is a final thickness of an elastomer, V is an application voltage (or actuating voltage), and εₒ and εᵣ are a dielectric constant of a free space and a dielectric constant of the polymer, respectively. Furthermore, deformation (δ_{z}) caused by the effective pressure (σ_{z}) is proportional to the square of the electric field. Accordingly, after the compression, the final thickness may be expressed by t=(1+δ_{z})tₒ.

If Equation 1 is modified using z-directional deformation (δ_{z}) caused by the effective pressure (σ_{z}), an equation of the third degree with respect to the deformation (δ_{z}), which is expressed by the following Equation 3, may be gained through the following Equation 2.

$$\begin{matrix}\begin{matrix}\frac{{σ}_{z}}{Y} = {δ}_{z} \\ = - \frac{1}{Y} {ɛ}_{o} {ɛ}_{r} ( \frac{V}{( 1 + {δ}_{z} ) {t}_{o}} ) \\ = - \frac{1}{Y} {ɛ}_{o} {{ɛ}_{r} ( \frac{V}{{t}_{o}} )}^{2} \frac{1}{{( 1 + {δ}_{z} )}^{2}}\end{matrix} & Equation 2 \\ {δ}_{z}^{3} + 2 {δ}_{z}^{2} + {δ}_{z} = - \frac{1}{Y} {ɛ}_{o} {{ɛ}_{r} ( \frac{V}{{t}_{o}} )}^{2} & Equation 3\end{matrix}$$

In Equations 2 and 3, Y is the tensile strength of a material.

FIG. 1 illustrates a curve, which shows deformation (δ_{z}) as a function of a voltage for the silicon material, based on Equation 3. In this regard, the silicon material has physical properties that include a tensile strength of 2, a breakdown strength of 20 kV/mm, and a relative dielectric constant of 2.8.

With reference to FIG. 1, the deformation (δ_{z}) is merely 0.25-3% in a voltage range within which the breakdown strength is allowed.

Since the dielectric polymer material is incompressible, radial deformation (δᵣ) may be expressed by the following Equation 4, assuming that the dielectric polymer film is of a disk shape.

$${δ}_{r} = \frac{1}{\sqrt{( 1 + {δ}_{z} )}} - 1 \qquad Equation 4$$

If an approximate value is gained through a series of Equation 4, radial deformation (δᵣ) may be −(½)δ_{z}.

Through the above description, it can be seen that radial deformation as well as vertical deformation of the dielectric polymer is very limiting. In other words, since the dielectric polymer material generates relatively small displacement and output in the course of using deformation caused by the compression force of an electric field, there are problems in practical application.

To avoid the above problems so as to assure high displacement and output, a dielectric polymer actuator, in which prestrain is applied to a dielectric polymer, has been recently developed. In a dielectric polymer film to which prestrain is applied, since stress remains in an elastomer and thus the film is deformed, elastic equilibrium is restructured. It is known that the dielectric polymer film, in which an elastic force is restructured by prestrain as described above, is capable of significantly increasing deformation by an electric field.

However, the prestrain negatively affects the dielectric polymer actuator.

In detail, when prestrain is applied to the dielectric polymer film, since the dielectric polymer of the actuator has predetermined deformation, stress relaxation, one of the typical mechanical properties, occurs. This brings about a gradual reduction in performance of the dielectric polymer actuator.

Furthermore, since a conventional dielectric polymer actuator requires an external structure in order to keep prestrain, the structure of the actuator is complicated and the weight increases regardless of power generation. Hence, the conventional dielectric polymer actuator has a disadvantage of reduced output efficiency to a weight.

Strictly speaking, the conventional dielectric polymer actuator employing prestrain is actuated in a passive actuating manner rather than an active actuating manner, and thus, a predetermined elastic force must be provided using an additional elastomer, such as a spring, installed outside the actuator. The output efficiency to the weight is reduced by half due to the additional elastomer, which is a significant obstacle to production of a subminiature actuator.

As described above, even though the conventional dielectric polymer actuator employing prestrain is advantageous in that a level of deformation is high to generate a useful level of displacement, since reliability is reduced due to stress relaxation and output to the weight is poor because of additional components, there is a limit to provide a miniaturized actuator having excellent reliability when using it for a long time.

### SUMMARY OF THE INVENTION

Accordingly, the present invention has been made keeping in mind the above problems occurring in the prior art, and an object of the present invention is to provide a novel dielectric polymer actuator, which is capable of providing desirable displacement without applying prestrain, which causes problems in the course of producing an excellent actuator.

Another object of the present invention is to provide an inchworm robot, which is capable of performing movement having 3 degrees of freedom, using the above dielectric polymer actuator.

In order to accomplish the above objects, the present invention provides a novel dielectric polymer actuator, which generates significant displacement and output without applying prestrain to a dielectric polymer film.

The dielectric polymer actuator according to the present invention comprises a laminate-type actuating part provided with at least one dielectric polymer film which has first and second surfaces positioned opposite to each other and a side surface interposed between the first and second surfaces and which includes an incompressible dielectric polymer, and first and second compliant electrodes connected to the first and second surfaces, respectively. A frame is formed along the side surface of the dielectric polymer film so that the prestrain applied to the dielectric polymer film is about zero. When a voltage is applied through the first and second compliant electrodes to the dielectric polymer film, the laminate-type actuating part is warped in any one direction of first and second surface directions to provide displacement corresponding to the voltage applied.

Preferably, the dielectric polymer film has a structure that is warped in a desired direction so as to induce displacement in the desired direction, and the dielectric polymer film has a disk shape.

Furthermore, the laminate-type actuating part has a structure, in which a plurality of dielectric polymer films are laminated, so as to assure desirable rigidity for displacement. At this stage, the first or second compliant electrode interposed between first and second dielectric polymer films of the dielectric polymer films acts as the second or first compliant electrode of a third dielectric polymer film adjacent to the second dielectric polymer film.

The laminate-type actuating part may further comprise an electrode protective film for protecting the first and second compliant electrodes forming uppermost and lowermost parts thereof.

It is preferable that one of the first and second compliant electrodes is spaced from a circumferential edge of the dielectric polymer film by a predetermined distance so as to be electrically insulated from the other of the first and second compliant electrodes.

To improve response characteristics, it is preferable that the dielectric polymer actuator further comprise a discharging part connected to the first and second compliant electrodes so as to remove an electric charge remaining on the dielectric polymer film after a predetermined voltage is applied. A circuit constituting the discharging part may be structured parallel to an actuating circuit for supplying an actuating voltage, and may be united with the actuating circuit to have discharging ability.

Furthermore, the present invention provides an inchworm robot using the dielectric polymer actuator.

The inchworm robot comprises a segmental actuating unit including a plurality of actuator modules laminated therein. An external structure surrounds the segmental actuating unit so as to protect the plurality of actuator modules. Segmental parts are formed between the plurality of actuator modules to allow displacement of the actuator modules. Power supplying units are electrically connected to the plurality of actuator modules to supply an actuating voltage. Each of the plurality of actuator modules comprises a substrate having upper and lower surfaces, a plurality of dielectric polymer actuators arranged on at least one surface of the substrate, and a circuit pattern formed on the substrate to apply a voltage to the plurality of dielectric polymer actuators therethrough. Each of the plurality of dielectric polymer actuators comprises a laminate-type actuating part and a frame. The laminate-type actuating part is provided with at least one dielectric polymer film which has first and second surfaces positioned opposite to each other and a side surface interposed between the first and second surfaces and which includes an incompressible dielectric polymer, and first and second compliant electrodes connected to the first and second surfaces to be connected to the circuit pattern. The frame is formed along the side surface of the dielectric polymer film so that prestrain applied to the dielectric polymer film is about zero, and adheres to the substrate.

Preferably, the laminate-type actuating part has a structure in which a plurality of dielectric polymer films are laminated, and the first or second compliant electrode interposed between first and second dielectric polymer films of the dielectric polymer films acts as the second or first compliant electrode of a third dielectric polymer film adjacent to the second dielectric polymer film.

Additionally, the substrate of each of the actuator modules is of a disk shape, and three pairs of dielectric polymer actuators of the actuator modules are arranged at equal intervals along a circumference of the substrate.

It is preferable that a circuit pattern of the actuator modules comprise a common earthed pattern connected to a plurality of dielectric polymer actuators, and three power supplying patterns connected to three pairs of dielectric polymer actuators.

As well, it is preferable that the inchworm robot further comprise discharging parts connected to the three power supplying patterns in parallel to the power supplying units so as to remove an electric charge remaining on the dielectric polymer film after a predetermined voltage is applied.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a graph showing deformation as a function of a voltage for a dielectric polymer consisting of silicone;

FIGS. 2a and 2b are a plan view and a sectional view of a dielectric polymer actuator according to the present invention;

FIGS. 3a to 3c illustrate the actuation of the dielectric polymer actuator according to the present invention;

FIG. 4 is a graph showing vertical displacement of the dielectric polymer actuator according to the present invention;

FIG. 5 is a graph showing response characteristics of the dielectric polymer actuator according to the present invention;

FIG. 6 is a graph showing output as a function of voltage for the dielectric polymer actuator according to the present invention;

FIG. 7a is an exploded perspective view of an inchworm robot according to the present invention;

FIG. 7b is an exploded perspective view of an actuator module adopted in FIG. 7a;

FIG. 8 is an image of the inchworm robot produced according to the present invention;

FIG. 9 illustrates an actuation circuit diagram including a discharging part, which is capable of being used in the dielectric polymer actuator, according to the present invention; and

FIGS. 10a and 10b are graphs showing frequency characteristics for a dielectric polymer actuator that is not provided with the discharging part, and for another dielectric polymer actuator that is provided with the discharging part, respectively.

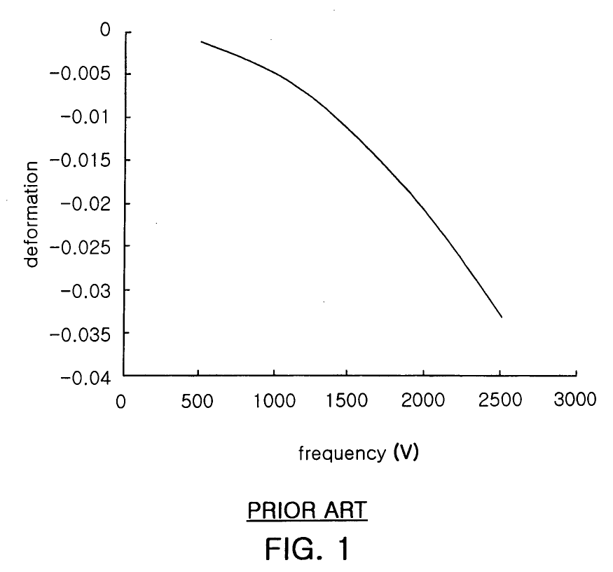

### DESCRIPTION OF THE PREFERRED EMBODIMENTS

Hereinafter, embodiments of the present invention will be described in more detail with reference to the drawings.

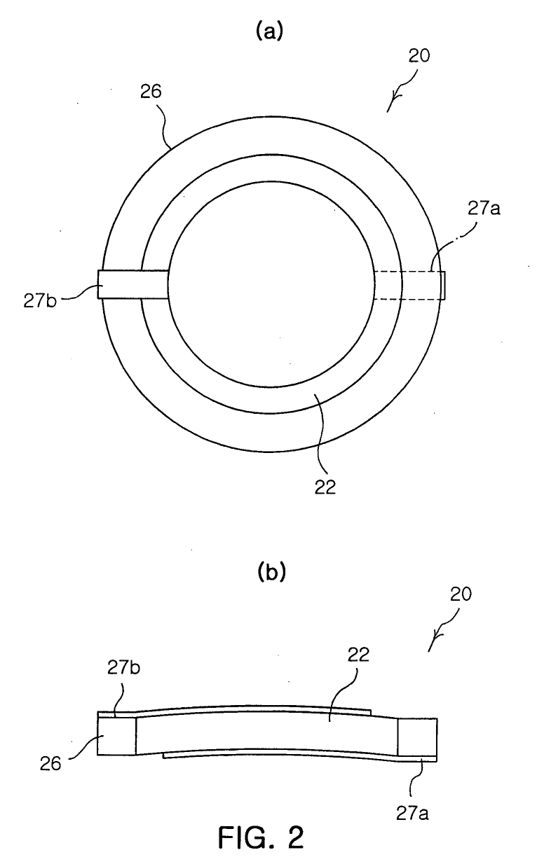

FIGS. 2a and 2b illustrate a dielectric polymer actuator according to the present invention.

Referring to FIG. 2a, the dielectric polymer actuator 20 comprises a laminate-type actuating part, which is provided with first and second compliant electrodes 27a, 27b and a dielectric polymer film 22 interposed between the electrodes, and a frame 26 which surrounds a circumferential surface of the dielectric polymer film 22. The frame 26 is provided on the circumferential surface of the dielectric polymer film so that prestrain applied to the dielectric polymer film 22 is about Zero.

The dielectric polymer film 22 may be made of an incompressible material which is selected from silicon, fluorine elastic polymer, polybutadiene, or isoprene. The dielectric polymer film 22 employed in the present invention is of a disk shape and thus the frame 26 is of a ring shape which has an internal diameter corresponding to the disk-shaped dielectric polymer film. The frame 26 may be made of a rigid material which is capable of blocking horizontal expansion, that is, radial expansion, of the dielectric polymer film 22. Furthermore, it is preferable that the dielectric polymer film 22 be warped in a predetermined direction so that displacement is induced in an upward or downward direction as desired. The diameter of the dielectric polymer film 22 is designed to be slightly larger than the internal diameter of the frame 26, thereby easily warping the dielectric polymer film.

The first and second compliant electrodes 27a, 27b function to provide a voltage therethrough to induce deformation of the dielectric polymer film 22, and may be made of carbon, graphite, or conductive polymer. As shown in FIGS. 2a and 2b, it is preferable that the compliant electrodes 27a, 27b be formed while they are spaced from an edge of the dielectric polymer film 22 by a predetermined distance so as to prevent a short circuit caused by undesired discharge between the compliant electrode 27a or 27b and another compliant electrode 27b or 27a.

As well, the laminate-type actuating part may further comprise an electrode protective film (not shown) for protecting the compliant electrodes 27a, 27b on the dielectric polymer film 22 to prevent damage caused by external impact.

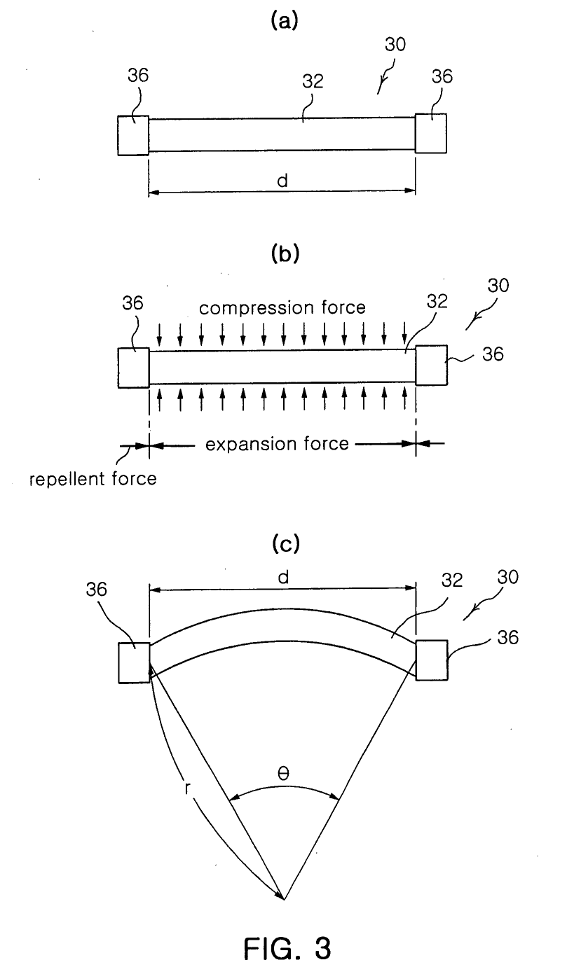

In the dielectric polymer actuator 20 according to the present invention, when a voltage is applied through the first and second compliant electrodes 27a, 27b to the dielectric polymer film 22, the incompressible dielectric polymer film 22 tries to radially expand. However, the expansion is blocked by the frame 26, thereby warping the film in either a first or a second surface direction, causing displacement. A detailed description will be given of the actuation of the dielectric polymer actuator of the present invention, with reference to FIGS. 3a to 3c.

FIGS. 3a to 3c are sectional views illustrating the actuation of a dielectric polymer actuator 30 according to the present invention. For convenience of description, the compliant electrodes are not shown even though they are provided on upper and lower surfaces of a dielectric polymer film 32 as in FIG. 2b.

Referring to FIG. 3a, the disk-shaped dielectric polymer film 32 having a predetermined diameter (d) is fixed by a frame 36 attached to a circumferential edge thereof. The dielectric polymer film 32 is made of an incompressible material, and the frame is made of a rigid material to suppress radial expansion of the dielectric polymer film 32 which is in an initial state before a voltage is applied.

When the voltage is applied to the dielectric polymer film 32, a compression force vertically acts on the dielectric polymer film 32 as shown in FIG. 3b. The compression force enables the incompressible dielectric polymer film 32 to expand. In other words, the dielectric polymer film 32 is apt to horizontally expand to maintain a constant volume. However, since the radial expansion is suppressed by the frame 36, a repellent force acts on the dielectric polymer film 32.

Through the action of the above forces, the central part of the dielectric polymer film 32 is uplifted and thus deformation occurs as shown in FIG. 3c, causing displacement (h) which is defined as a vertical position shift of the central part. Furthermore, if the dielectric polymer film 32 is of a disk shape, since forces radially uniformly act over the whole film, the deformed film forms a partial sphere. Therefore, as shown in FIG. 3c, the deformed film may be expressed by a radius of curvature (r) and an angle (θ).

The displacement (h) may be defined by the following Equation 5, assuming that deformation is δ_{z}.
h=d(1+δₐ)=rθ Equation 5

Since r(sin θ/2) d/2, if this is substituted for d of Equation 5 and sin (θ/2) is spread using a second degree of series, θ may be expressed by the following Equation 6.
θ={square root over (24(1−1/(1+δₐ)))} Equation 6

δₐ is calculated using Equations 2 to 4 to calculate θ. Since the radius of curvature (R) is [(1+δₐ)d]/θ, the displacement (h) as the resulting target may be defined by the following Equation 7.
h=r(1−cos(θ/2)) Equation 7

As described above, the present invention can achieve effective actuation without the use of prestrain.

Hereinafter, a detailed description will be given of the operation and effect of the present invention through the following examples which are set forth to illustrate, but are not to be construed as the limits of the present invention.

### EXAMPLE 1

To evaluate the operation and effect of a dielectric polymer actuator of the present invention, twenty disk-shaped dielectric polymer thin films each having a thickness of 35 μm and a diameter of 5.8 mm were prepared, and were alternately laminated in conjunction with carbon powder electrodes, acting as compliant electrodes, to produce a laminate-type actuating part. In the laminate-type actuating part, each compliant electrode was interposed between the dielectric polymer films to enable the first or second compliant electrode of the dielectric polymer film to act as the second or first compliant electrode of the adjacent dielectric polymer film.

The compliant electrodes were formed while being spaced from a circumferential edge of the dielectric polymer thin film by a distance of about 0.35 mm so as to insulate the electrodes from each other (referring to FIG. 2a, the circular part of the electrode was 5.1 mm in diameter).

Furthermore, electrode protective films were further provided on upper and lower surfaces of the laminate-type actuating part so as to protect the electrodes forming uppermost and lowermost parts (the total thickness of the laminate-type actuating part was 750 μm).

The laminate-type actuating part was fixed by a ring-shaped frame having an internal diameter of 5.7 mm to produce a dielectric polymer actuator according to the present example. Since a diameter of the laminate-type actuating part was smaller than the internal diameter of the frame by about 0.1 mm, the actuating part was unidirectionally warped, and a displacement direction of the laminate-type actuating part was determined by the warp direction.

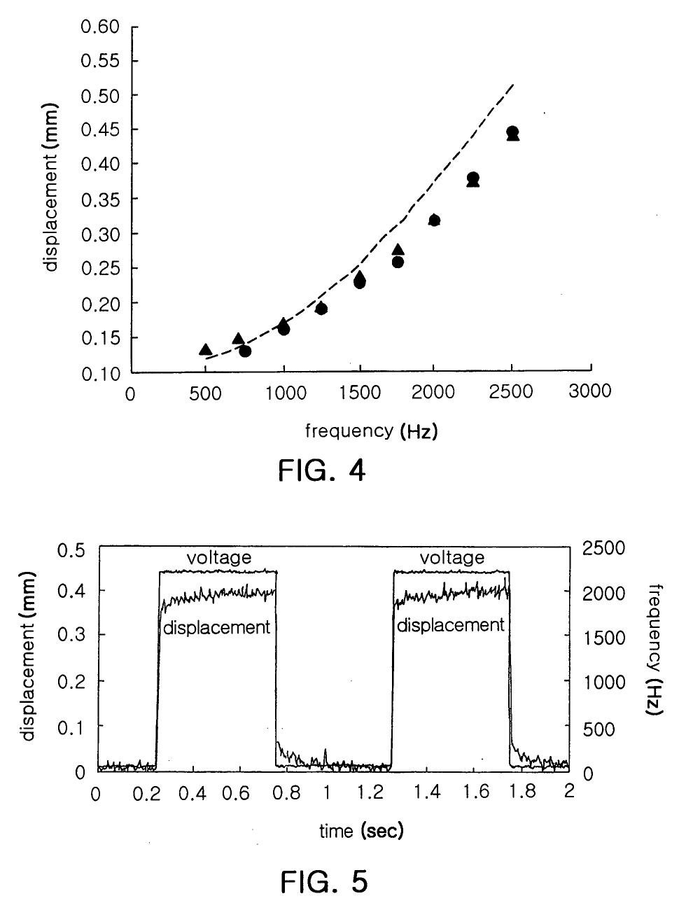

The level of displacement of the dielectric polymer actuator according to the present example was measured twice while an actuating voltage was changed from 500 V to 2500 V. The measurement results are shown in FIG. 4.

With reference to FIG. 4, the measurements are expressed by triangles and circles, and the displacement measurements range from 0.13 mm to 0.45 mm. It can be seen that the measurement results are almost the same as the results of simulation (dotted line) by Equation 7 except for a slight error caused by a difference in thickness between the dielectric thin films or the effect of the electrode protective films.

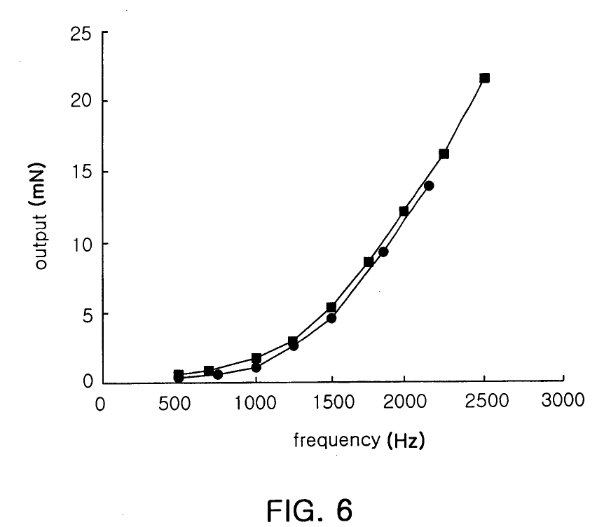

Additionally, response characteristics of the dielectric polymer actuator according to the present example were evaluated. 2.2 kV actuating voltage, which acted as a square wave and had a frequency of 1 Hz, was used to conduct the evaluation. The results are illustrated in FIG. 5. From FIG. 5, it can be seen that the response characteristics are very fast against the two sequential applications of the actuating voltage.

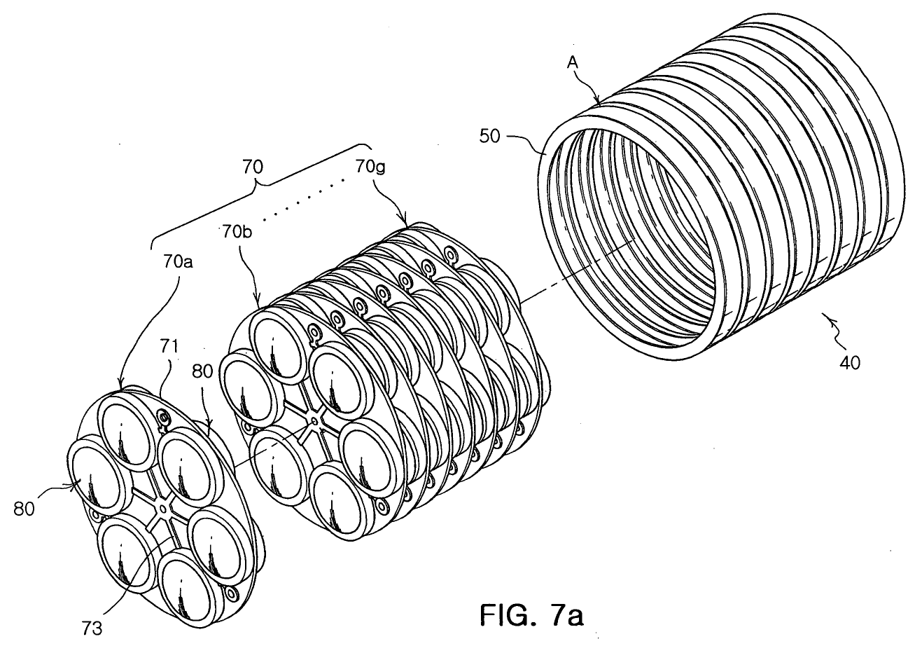

Finally, FIG. 6 is a graph showing an output as a function of a voltage of the dielectric polymer actuator according to the present example. From two sequential tests (rectangles and circles), it can be confirmed that the output is almost linearly changed at the actuating voltage of 1000 V or more.

The present invention also provides an inchworm robot which is capable of performing movement having 3 degrees of freedom using the above dielectric polymer actuator.

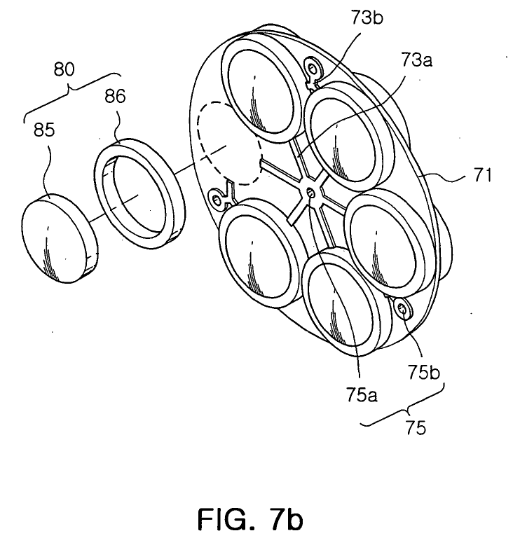

FIG. 7a is an exploded perspective view of an inchworm robot 40 according to the present invention.

Referring to FIG. 7a, the inchworm robot 40 comprises a segmental actuating unit 70 which is provided with a plurality of actuator modules 70a to 70g, and an external structure 50 for protecting a plurality of actuator modules 70a to 70g from external dust and the like. The inchworm robot 40 also comprises a power supplying unit (not shown) electrically connected to a plurality of actuator modules 70a to 70g to supply an actuating voltage.

As shown in FIG. 7b, each of the actuator modules 70a to 70g comprises a substrate 71 having upper and lower surfaces, twelve dielectric polymer actuators 80 provided on both sides of the substrate 71, and a circuit pattern 73 formed on the substrate 71 to apply the voltage to the twelve actuators 80.

Furthermore, each of the dielectric polymer actuators 80 has a structure that is similar to that of FIGS. 2 and 3. In other words, as shown in FIG. 7b, each of the dielectric polymer actuators 80 comprises a laminate-type actuating part 85 which is provided with at least one dielectric polymer film and first and second compliant electrodes connected to upper and lower surfaces of the film and connected to the circuit pattern 73, and a frame 86, which is formed along a circumference of the dielectric polymer film so that prestrain applied to the dielectric polymer film is about zero, and which adheres to the substrate 71.

As described above, the laminate-type actuating part 80 has a structure in which a plurality of dielectric polymer films are laminated so as to improve the rigidity thereof. Additionally, the first or second compliant electrode interposed between first and second dielectric polymer films of the dielectric polymer films acts as the second or first compliant electrode of a third dielectric polymer film adjacent to the second dielectric polymer film.

As in the present example, when the substrate 71 of the actuator module 70a is of a circular shape, it is preferable that the twelve dielectric polymer actuators 80 of the actuator module 70a be formed in such a way that three pairs of actuators 80 are formed at regular intervals along a circumference of the substrate 71 on the upper and lower surfaces of the substrate 71 so as to realize better movement having 3 degrees of freedom.

However, the number and arrangement of the actuators are not limited to the present example, but the actuators may be alternatively arranged and the number of the actuators may be varied. Additionally, the actuators may be selectively arranged on either the upper or lower surface of the substrate. For example, even if the three actuators are arranged on one surface of the substrate along the circumference of the substrate at regular intervals, it is possible to realize movement having 3 degrees of freedom.

Furthermore, as shown in FIG. 7b, the circuit pattern 73 of the substrate 71 may include a common earthed pattern 73a connected to all the dielectric polymer actuators 80 (first compliant electrode), and three power supplying patterns 73b connected to three pairs of dielectric polymer actuators 80 (second compliant electrode). As well, connection holes 75a, 75b are formed through the common earthed pattern 73a and the power supplying patterns 73b and through the substrate 71. Accordingly, it is possible to simultaneously actuate the actuators 80 of the module 70a using connection units (not shown), such as electric wires including enameled wires, and it is possible to provide movement in a sequential actuating manner by independently controlling the actuators.

As shown in FIG. 7a, the external structure 50 may be made using silicone, which is harmless to humans and has high tensile strength and elongation, in a predetermined 3D molding manner. Particularly, it is preferable that the external structure 50 employed in the present invention have a structure, in which wrinkles (A) are formed depending on an interval between the modules, so as to allow shrinkage and expansion movements of the actuator modules 70.

### EXAMPLE 2

In the present example, an inchworm robot as shown in FIG. 7a was produced. First, a segmental actuating unit, which was provided with eight actuator modules laminated thereon, was produced. Twelve dielectric polymer actuators, which were produced in example 1, were arranged as shown in FIG. 7b to produce actuator modules. A diameter and a height of each module were set to 20 mm and 3 mm, respectively, and a weight of the module was 0.4 g. Connection between modules was achieved by attaching insulators, which each had a diameter of 1 mm and a height of 0.2-0.4 mm (control of a height difference between the actuators), to the tops of the actuators using a silicone resin.

As well, power was supplied through four strands of enameled wires each having a diameter of 80 μm (one strand for a common earthed pattern and three strands for power supplying patterns) to the actuators of the actuator modules. An external structure of the segmental actuating unit was made of a silicone material, in which wrinkles were formed between the modules in order to make segmental movement possible, so as to have a thickness of 100 μm.

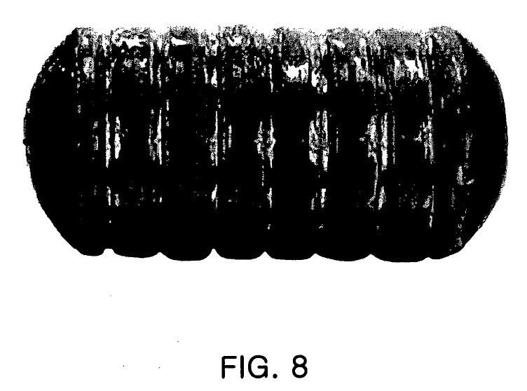

Thereby, the inchworm robot having a diameter of 20 mm and a length of 45 mm was produced as shown in FIG. 8. Since the inchworm robot was made of relatively light silicone or a polymer material except for the electric wires and the patterns thereof, the total weight was only 4.7 g.

Moving speed and load of the inchworm robot of the present example were evaluated, and the results were that the moving speed was 2.5 mm/sec and the load was 10 kg or more.

As described above, it is possible to produce a novel robot structure, which is miniaturized and light, using expansion of the dielectric polymer actuator while use of prestrain is excluded. Additionally, it is possible to design the robot structure so that the robot structure has 3 degrees of freedom to move the tube-shaped external structure. The inchworm robot according to the present example may include various types of robots having a basic frame and an actuating unit.

As well, the present invention provides an actuating circuit which is capable of solving problems of reduction of displacement and output at a predetermined frequency or higher. The reduction of displacement and output occurs because an actuating voltage substantially applied to the actuator is smaller than an input voltage due to an electric charge remaining on the dielectric film when the actuating frequency is high. To avoid the above problems, the present invention provides an actuator, that is, an actuating part which further includes a discharging circuit for discharging any electric charge remaining on the dielectric film.

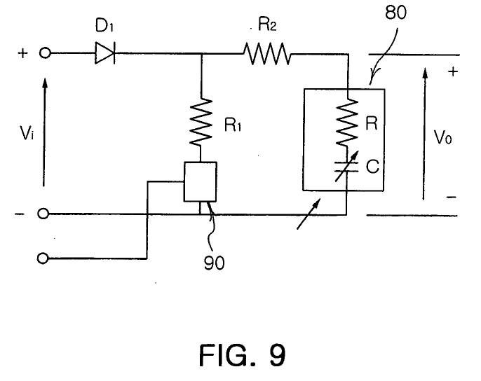

FIG. 9 illustrates an actuation circuit diagram containing discharging parts which are used in the dielectric polymer actuator according to the present invention.

Referring to FIG. 9, an equivalent circuit for the dielectric polymer actuator 80 is designated by R and C. The dielectric polymer actuator 80 has a predetermined output voltage (Vₒ) to an input voltage (Vᵢ) applied from power supplying units. The discharging parts 90 are operated so as to act in concert with a signal for application of an input voltage, thereby quickly discharging the remaining electric charge when the input voltage is removed, resulting in significantly improved frequency response characteristics.

At this stage, if the actuator has a structure that is the same as that of example 2, it is possible to form the discharging parts 90 connected to three power supplying patterns in parallel to the power supplying units.

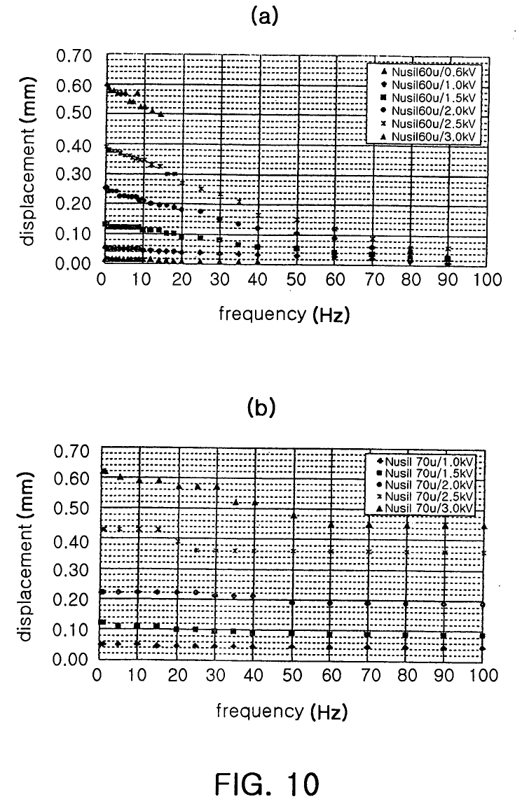

FIGS. 10a and 10b are graphs showing frequency characteristics for a dielectric polymer actuator which is not provided with a discharging part, and for a dielectric polymer actuator which is provided with a discharging part.

As shown in FIG. 10a, in the actuator which is not provided with the discharging part, displacement is rapidly reduced while a frequency increases to 10 Hz or more. On the other hand, as shown in FIG. 10b, in the actuator which is provided with a power supplying unit and a discharging part connected in parallel to the power supplying unit, reduction of displacement is small at an actuating frequency of 100 Hz, and particularly, displacement variation is insignificant at 1.0-2.0 kV.

As described above, the use of the discharging part, which is connected in parallel to the power supplying unit, significantly improves response performances of the actuator.

The present invention has been described in an illustrative manner, and it is to be understood that the terminology used is intended to be in the nature of description rather than of limitation. Many modifications and variations of the present invention are possible in light of the above teachings. Therefore, it is to be understood that within the scope of the appended claims, the invention may be practiced otherwise than as specifically described.

As described above, the present invention provides an excellent dielectric polymer actuator, which assures desirable displacement without employing prestrain. Furthermore, the present invention provides an inchworm robot which is capable of performing movement having 3 degrees of freedom using the above dielectric polymer actuator.

Additionally, the actuator according to the present invention employs a discharging part applied to an actuation circuit, thereby overcoming problems caused by the remaining electric charge, resulting in significantly improved frequency response characteristics.

As described above, an actuator using the dielectric polymer according to the present invention is advantageous in that performance of the actuator is stable over time, and that it is possible to produce a light and miniaturized actuator because an external structure is excluded as far as possible, compared to an actuator using prestrain.

1. A dielectric polymer actuator, comprising:
a laminate-type actuating part, comprising:
at least one dielectric polymer film which has first and second surfaces positioned opposite to each other and a side surface interposed between the first and second surfaces and which includes an incompressible dielectric polymer; and
first and second compliant electrodes connected to the first and second surfaces, respectively; and
a frame formed along the side surface of the dielectric polymer film so that prestrain applied to the dielectric polymer film is about zero,
wherein, when a voltage is applied through the first and second compliant electrodes to the dielectric polymer film, the laminate-type actuating part is warped in any one direction of first and second surface directions to provide displacement corresponding to the voltage applied.

2. The dielectric polymer actuator as set forth in claim 1, further comprising a discharging part connected to the first and second compliant electrodes so as to remove an electric charge remaining on the dielectric polymer film after a predetermined voltage is applied.

3. The dielectric polymer actuator as set forth in claim 1, wherein the dielectric polymer film has a structure that is warped in a desired direction so as to induce displacement in the desired direction.

4. The dielectric polymer actuator as set forth in claim 3, further comprising a discharging part connected to the first and second compliant electrodes so as to remove an electric charge remaining on the dielectric polymer film after a predetermined voltage is applied.

5. The dielectric polymer actuator as set forth in claim 1, wherein the dielectric polymer film has a disk shape.

6. The dielectric polymer actuator as set forth in claim 5, further comprising a discharging part connected to the first and second compliant electrodes so as to remove an electric charge remaining on the dielectric polymer film after a predetermined voltage is applied.

7. The dielectric polymer actuator as set forth in claim 1, wherein the laminate-type actuating part has a structure such that a plurality of dielectric polymer films is laminated, and the first or second compliant electrode interposed between first and second dielectric polymer films of the dielectric polymer films acts as the second or first compliant electrode of a third dielectric polymer film adjacent to the second dielectric polymer film.

8. The dielectric polymer actuator as set forth in claim 7, wherein the laminate-type actuating part further comprises an electrode protective film for protecting the first and second compliant electrodes forming uppermost and lowermost parts thereof.

9. The dielectric polymer actuator as set forth in claim 8, further comprising a discharging part connected to the first and second compliant electrodes so as to remove an electric charge remaining on the dielectric polymer film after a predetermined voltage is applied.

10. The dielectric polymer actuator as set forth in claim 1, wherein one of the first and second compliant electrodes is spaced from a circumferential edge of the dielectric polymer film by a predetermined distance so as to be electrically insulated from the other of the first and second compliant electrodes.

11. The dielectric polymer actuator as set forth in claim 10, further comprising a discharging part connected to the first and second compliant electrodes so as to remove an electric charge remaining on the dielectric polymer film after a predetermined voltage is applied.

12. An inchworm robot, comprising:
a segmental actuating unit including a plurality of actuator modules laminated therein;
an external structure which surrounds the segmental actuating unit so as to protect the plurality of actuator modules and in which segmental parts are formed between the plurality of actuator modules to allow displacement of the actuator modules; and
power supplying units electrically connected to the plurality of actuator modules to supply an actuating voltage,
wherein each of the plurality of actuator modules comprises a substrate having upper and lower surfaces, a plurality of dielectric polymer actuators arranged on at least one surface of the substrate, and a circuit pattern formed on the substrate to apply a voltage to the plurality of dielectric polymer actuators therethrough, and
each of the plurality of dielectric polymer actuators comprises a laminate-type actuating part and a frame, the laminate-type actuating part being provided with at least one dielectric polymer film which has first and second surfaces positioned opposite to each other and a side surface interposed between the first and second surfaces and including an incompressible dielectric polymer and first and second compliant electrodes connected to the first and second surfaces to be connected to the circuit pattern, and the frame being formed along the side surface of the dielectric polymer film so that prestrain applied to the dielectric polymer film is about zero and adhering to the substrate.

13. The inchworm robot as set forth in claim 12, further comprising discharging parts connected to the three power supplying patterns in parallel to the power supplying units so as to remove an electric charge remaining on the dielectric polymer film after a predetermined voltage is applied.

14. The inchworm robot as set forth in claim 12, wherein the laminate-type actuating part has a structure in which a plurality of dielectric polymer films are laminated, and the first or second compliant electrode interposed between first and second dielectric polymer films of the dielectric polymer films acts as the second or first compliant electrode of a third dielectric polymer film adjacent to the second dielectric polymer film.

15. The inchworm robot as set forth in claim 14, further comprising discharging parts connected to the three power supplying patterns in parallel to the power supplying units so as to remove an electric charge remaining on the dielectric polymer film after a predetermined voltage is applied.

16. The inchworm robot as set forth in claim 12, wherein the substrate of each of the actuator modules is of a disk shape, and three pairs of dielectric polymer actuators of the actuator modules are arranged at equal intervals along a circumference of the substrate.

17. The inchworm robot as set forth in claim 16, wherein a circuit pattern of the actuator modules comprises a common earthed pattern connected to a plurality of dielectric polymer actuators, and three power supplying patterns connected to three pairs of dielectric polymer actuators.

18. The inchworm robot as set forth in claim 17, further comprising discharging parts connected to the three power supplying patterns in parallel to the power supplying units so as to remove an electric charge remaining on the dielectric polymer film after a predetermined voltage is applied.
